(19) United States
(12) Patent Application Publication
(10) Pub. No.: US 2025/0218857 A1
(43) Pub. Date: Jul. 3, 2025

(54) SUBSTRATE PROCESSING APPARATUS

(71) Applicant: SEMES CO., LTD., Cheonan-si (KR)

(72) Inventors: In Ki JUNG, Hwaseong-si (KR); Jun Ho SONG, Hwaseong-si (KR); Ho Jong HWANG, Hwaseong-si (KR); Se Hoon OH, Cheonan-si (KR); Jeong Hyup YU, Hwaseong-si (KR)

(73) Assignee: SEMES CO., LTD., Cheonan-si (KR)

(21) Appl. No.: 19/005,141

(22) Filed: Dec. 30, 2024

(30) Foreign Application Priority Data
Dec. 29, 2023 (KR) 10-2023-0196046

(51) Int. Cl. H01L 21/687; H01L 21/67

(52) U.S. Cl. CPC H01L 21/6875; H01L 21/67051; H01L 21/68764

(57) ABSTRACT

Disclosed is an apparatus of treating a substrate, which is capable of reducing stress applied to a chuck pin while simultaneously driving a guide ring unit and the chuck pin. The apparatus includes: a cup body having a treatment space therein and an open top; a support unit for supporting a substrate within the treatment space; a liquid supply unit for supplying a treatment liquid to a substrate supported by the support unit; and a contact part provided to be movable in an up and down direction, in which the support unit includes: a support plate on which the substrate is placed and which is provided to be rotatable; a chuck pin provided on the support plate and supporting the substrate on a side portion of the substrate; and a chuck pin support that is coupled to the chuck pin and supports the chuck pin, and the contact part is in contact with an inclined surface formed on the chuck pin support when the contact part rises, the chuck pin is provided to move between a spaced position and a support position by an up and down movement of the contact part, the spaced position is a position spaced apart from the substrate supported by the support unit, and the support position is a position that supports the side portion of the substrate supported by the support unit.

### CROSS-REFERENCE TO RELATED APPLICATIONS

This application claims priority to and the benefit of Korean Patent Application No. 10-2023-0196046 filed in the Korean Intellectual Property Office on Dec. 29, 2023, the entire contents of which are incorporated herein by reference.

### TECHNICAL FIELD

The present invention relates to an apparatus and a method of treating a substrate, and more particularly, to a substrate processing apparatus capable of reducing stress applied to a chuck pin while simultaneously driving a guide ring unit and the chuck pin.

### BACKGROUND ART

A semiconductor process includes a process of cleaning a thin film, foreign substances, particles, and the like on a substrate. The cleaning process is performed by placing a substrate on a support unit and supplying a treatment liquid to an upper surface of the substrate while rotating the support unit. The substrate supported by the support unit fixes the substrate by a chuck pin. The chuck pin supports the substrate at the side of the substrate. However, when supporting the side of the substrate, as a rotational speed of the support unit increases, the support force of the chuck pin and the centrifugal force applied to the chuck pin may be offset, and thus the support force of the chuck pin may weaken.

Thus, as disclosed in Korean Patent No. 10-0873153, a contact maintaining member for maintaining the supporting force of the chuck pin by compensating for the offset supporting force is provided. The contact maintaining member generates centrifugal force in a direction toward the center of the support unit when the support unit is rotated. Thus, the supporting force of the chuck pin may be maintained. However, if the rotational speed continues to increase, the centrifugal force generated from the contact maintaining member becomes stronger, and the support force of the chuck pin may increase excessively. In this case, the risk of damage or deformation of the chuck pin increases, and the force transmitted to the substrate becomes stronger, which may cause bending or damage of the substrate.

In addition, as the rotational speed of the support unit increases, the scattering amount and scattering range of the treatment liquid scattered from the substrate may increase. Therefore, it is necessary to recover the treatment liquid scattered at a position more adjacent to the substrate than the cup. However, when a configuration of recovering the treatment liquid at a position more adjacent to the substrate than the cup is provided, there is a problem in that interference with a transfer robot entering the support unit to load or unload the substrate occurs.

### SUMMARY OF THE INVENTION

The present invention has been made in an effort to provide a substrate processing apparatus capable of preventing excessive increase in stress applied to a chuck pin.

The present invention has also been made in an effort to provide a substrate processing apparatus capable of preventing a substrate from being bent or damaged.

The present invention has also been made in an effort to provide a substrate processing apparatus capable of efficiently recovering a treatment liquid scattered from a rotating substrate.

The present invention has also been made in an effort to provide a substrate processing apparatus capable of eliminating interference between a transfer robot entering to load or unload a substrate and a guide ring unit that recovers a treatment liquid scattered from a substrate at a location adjacent to the substrate.

The present invention has also been made in an effort to provide a substrate processing apparatus capable of driving a guide ring unit along with a movement of a chuck pin.

The present invention has also been made in an effort to provide a substrate processing apparatus capable of transferring a substrate without adjusting a height of a spin chuck in a substrate processing apparatus that provides a guide ring and a back nozzle.

The problem to be solved by the present invention is not limited to the above-mentioned problems, and the problems not mentioned will be clearly understood by those skilled in the art from the descriptions below.

An exemplary embodiment of the present invention provides, an apparatus of treating a substrate, the apparatus comprising: a cup body having a treatment space therein and an open top; a support unit for supporting a substrate within the treatment space; a liquid supply unit for supplying a treatment liquid to a substrate supported by the support unit; and a contact part provided to be movable in an up and down direction, wherein the support unit includes: a support plate on which the substrate is placed and which is provided to be rotatable; a chuck pin provided on the support plate and supporting the substrate on a side portion of the substrate; and a chuck pin support that is coupled to the chuck pin and supports the chuck pin, and the contact part is in contact with an inclined surface formed on the chuck pin support when the contact part rises, the chuck pin is provided to move between a spaced position and a support position by an up and down movement of the contact part, the spaced position is a position spaced apart from the substrate supported by the support unit, and the support position may be a position that supports the side portion of the substrate supported by the support unit.

According to the exemplary embodiment of the present invention, when the chuck pin is located at the support position, the chuck pin support may be blocked from moving in a direction away from a enter of the support plate by the contact part disposed on a movement path of the chuck pin support.

According to the exemplary embodiment of the present invention, the chuck pin may be moved to the spaced position by a first elastic member installed on the chuck pin support.

According to the exemplary embodiment of the present invention, the inclined surface is formed at a lower end of an extension part formed by extending in a vertical direction from an inner end of the chuck pin support, and the extension part may include a vertical surface that is in contact with the contact part when the chuck pin is positioned at the support position.

According to the exemplary embodiment of the present invention, when the chuck pin is in the spaced position, the inclined surface and the contact part are provided to partially overlap when viewed from above, and the contact part may has a surface contacting the inclined surface in a form of a curved surface.

According to the exemplary embodiment of the present invention, the inclined surface may be provided to be inclined downwardly toward the support plate.

According to the exemplary embodiment of the present invention, the apparatus may further include a guide ring unit for guiding the treatment liquid scattered from the substrate to the cup body; and a driver for adjusting a height of the guide ring unit, wherein the guide ring unit further includes: a guide ring for guiding a treatment liquid scattered from the substrate to the cup body; and a guide ring support in which the guide ring is installed, and the contact part may be formed on the guide ring support.

According to the exemplary embodiment of the present invention, the driver adjusts a height of the guide ring unit so that the guide ring unit is located at a process position and a waiting position, the process position is a position higher than the support plate, the waiting position is a position lower than the support plate, and the chuck pin is moved to the support position when the guide ring unit is moved to the process position, and is moved to the spaced position when the guide ring unit may be moved to the waiting position.

An exemplary embodiment of the present invention provides, an apparatus of treating a substrate, the apparatus comprising: a cup body having a treatment space therein and an open top; a support unit for supporting a substrate within the treatment space; a liquid supply unit for supplying a treatment liquid to an upper surface of the substrate supported by the support unit; a guide ring unit for guiding the treatment liquid scattered from the substrate to the cup body; and a driver for adjusting a height of the guide ring unit, wherein the support unit includes: a support plate on which the substrate is placed and which is provided to be rotatable; a chuck pin provided on the support plate and supporting the substrate on a side portion of the substrate; and a chuck pin support coupled to the chuck pin and supporting the chuck pin, and wherein the guide ring unit further includes: a guide ring for guiding a treatment liquid scattered from the substrate to the cup body; and a guide ring support in which the guide ring is installed, and the guide ring unit may be moved by the driver between a process position, which is a position higher than the support plate, and a waiting position, which is a position lower than the support plate, and the guide ring support is in contact with the chuck pin support to move the chuck pin while the guide ring unit may be moved.

According to the exemplary embodiment of the present invention, the chuck pin is provided to be movable between a support position and a spaced position by the chuck pin support, the support position is a position where the chuck pin supports the substrate on a side portion of the substrate, and the spaced position may be a position where the chuck pin is spaced apart from the substrate.

According to the exemplary embodiment of the present invention, the chuck pin support is formed with an extension part extending in a vertical direction from an inner end of the chuck pin support, the guide ring support is formed with a contact part that is in contact with the extension part when the guide ring unit is moved to the process position, and when viewed from above, the extension part and the contact part partially overlap each other while the guide ring unit has moved to the waiting position, and the extension part may be located to be closer to the rotating shaft than the contact part.

According to the exemplary embodiment of the present invention, a sidewall of the extension part includes an inclined surface, the inclined surface is provided to be inclined downwardly toward the rotating shaft, and a surface of the contact part may be formed with a curved surface.

According to the exemplary embodiment of the present invention, as the guide ring unit moves to the process position, the contact part contacts a vertical wall of the sidewalls of the extension part, and the chuck pin may moves from the spaced position to the support position.

According to the exemplary embodiment of the present invention, a second elastic member may be provided at an inner end of the chuck pin support, and the second elastic member is provided to be compressed when the chuck pin is moved to the support position.

According to the exemplary embodiment of the present invention, the treatment liquid is provided as a first treatment liquid or a second treatment liquid different from the first liquid, the guide ring includes: an upper ring; a lower ring facing the upper ring in an up and down direction; and an intermediate ring disposed between the upper ring and the lower ring, and the upper ring, the intermediate ring, and the lower ring are fixed to each other by a fixing rod, and the fixing rod is coupled to the guide ring support, and when the guide ring unit is located in the process position, a height of the intermediate ring corresponds to a height of the substrate supported by the support unit.

According to the exemplary embodiment of the present invention, the liquid supply unit may include: a first nozzle for discharging the first treatment liquid to an upper surface of the substrate; and a second nozzle for discharging the second treatment liquid to a lower surface of the substrate.

According to the exemplary embodiment of the present invention, the cup body includes a plurality of cups, the plurality of cups is provided to surround different cups, and the first treatment liquid and the second treatment liquid may be recovered into different cups.

An exemplary embodiment of the present invention provides, an apparatus of treating a substrate, the apparatus comprising: a cup body having a treatment space therein and an open top; a support unit for supporting a substrate within the treatment space; a guide ring unit for guiding the treatment liquid scattered from the substrate to the cup body; and the liquid supply unit including a first nozzle for supplying a first treatment liquid to an upper surface of the substrate supported by the support unit and a second nozzle for supplying a second treatment liquid to a lower surface of the substrate, and a driving unit for driving the guide ring unit and the support unit, the cup body includes a plurality of cups, the plurality of cups is provided to surround different cups, and the first treatment liquid and the second treatment liquid are recovered into different cups, the support unit includes: a support plate on which the substrate is placed; a chuck pin provided on the support plate and supporting the substrate on a side portion of the substrate; a rotating shaft supporting the support plate at a center of a lower surface of the support plate; anda chuck pin support for supporting the chuck pin by being coupled with the chuck pin, the guide ring unit includes: a guide ring for guiding the first treatment liquid and the second treatment liquid scattered from the substrate to the cup body; and a guide ring support in which the guide ring is installed, and which is installed inside the support plate by penetrating from a lower portion of the support plate to an inside of the support plate, and the guide ring unit is moved between a process position that is a position higher than the support plate and a waiting position that is a position lower than the support plate by the driving unit, the driving unit includes: a first driver for adjusting a relative height between the guide ring unit and the support plate; and a second driver for rotating the rotating shaft, a connection part connecting the guide ring unit and the first driver is detachably provided during treatment of the substrate, the chuck pin is provided to be movable between a support position and a spaced position by the chuck pin support, and the support position is a position where the chuck pin supports the substrate on a side portion of the substrate, and the spaced position is a position where the chuck pin is spaced from the substrate, the chuck pin support is formed with an extension part extending in a vertical direction from an inner end of the chuck pin support, a sidewall of the extension part has a vertical surface, and an inclined surface which extends while being inclined downwardly from the vertical surface toward the rotating shaft, the guide ring support is formed with a contact part that is in contact with the extension part when the guide ring unit is moved to the process position, and a curved surface is formed on a surface of the contact part, when the guide ring unit has moved to the waiting position, the extension part and the contact part partially overlap each other when viewed from above, and the extension part is located to be closer to the rotating shaft than the contact part, when the guide ring unit moves to the process position, the contact part sequentially contacts the inclined surface and the vertical surface of the extension part to move the chuck pin from the spaced position to the support position, and a second elastic member is provided at an inner end of the chuck pin support, and the second elastic member may be provided to be compressed when the chuck pin is moved to the support position.

According to the exemplary embodiment of the present invention, the guide ring includes: an upper ring; a lower ring facing the upper ring in an up and down direction; and an intermediate ring disposed between the upper ring and the lower ring, and the upper ring, the intermediate ring, and the lower ring are fixed to each other by a fixing rod, and the fixing rod is coupled to the guide ring support, and when the guide ring unit is located in the process position, a height of the intermediate ring corresponds to a height of the substrate supported by the support unit.

According to the exemplary embodiment of the present invention, a first elastic member may be installed under the guide ring support, and the first elastic member applies elastic force to the guide ring support so as to make the guide ring support face upwardly.

According to the exemplary embodiment of the present invention, it is possible to prevent excessive increase in stress applied to a chuck pin.

Further, according to the exemplary embodiment of the present invention, it is possible to prevent a substrate from being bent or damaged.

Further, according to the exemplary embodiment of the present invention, it is possible to efficiently recover a treatment liquid scattered from a rotating substrate.

Further, according to the exemplary embodiment of the present invention, it is possible to eliminate interference between a transfer robot entering to load or unload a substrate and a guide ring unit that recovers a treatment liquid scattered from a substrate at a location adjacent to the substrate.

Further, according to the exemplary embodiment of the present invention, it is possible to drive a guide ring unit along with a movement of a chuck pin.

Further, according to the exemplary embodiment of the present invention, it is possible to transfer a substrate without adjusting a height of a spin chuck in a substrate processing apparatus that provides a guide ring and a back nozzle.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a diagram schematically illustrating a substrate processing apparatus according to an exemplary embodiment of the present invention.

FIG. 2 is a diagram schematically illustrating an exemplary embodiment of a liquid treating chamber of FIG. 1.

FIG. 3 is a diagram illustrating a support unit and a guide ring unit in the liquid treating chamber of FIG. 2 in more detail.

FIG. 4 is a diagram illustrating a chuck pin and a chuck pin support when the chuck pin supports a substrate in the liquid treating chamber of FIG. 2.

FIG. 5 is a diagram illustrating a state viewed from above when a first plate and a second plate are at a first position.

FIG. 6 is a diagram illustrating a state viewed from above when the first plate and the second plate are at a second position.

FIG. 7 is a diagram schematically illustrating another exemplary embodiment of the liquid treating chamber of FIG. 1.

FIG. 8 is a diagram illustrating the support unit of FIG. 7 in more detail.

FIG. 9 is a cross-sectional view illustrating a cross-section of the liquid treating chamber according to the exemplary embodiment of the present invention before a substrate is loaded onto the support unit.

FIG. 10 to FIG. 13 are diagrams illustrating the appearance of an extension part and a contact part while the guide ring unit moves to a process position and the chuck pin moves to a support position.

FIG. 14 is a diagram illustrating a state of treating a substrate in the liquid treating chamber according to the exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

Hereinafter, exemplary embodiments of the present invention will be described with reference to the accompanying drawings.

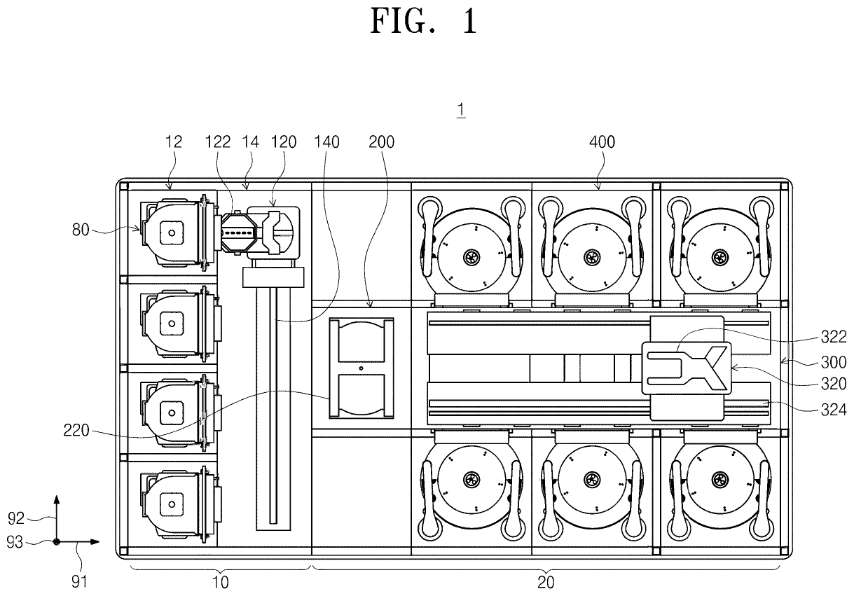

FIG. 1 is a top plan view schematically illustrating a substrate processing apparatus according to an exemplary embodiment of the present invention.

Referring to FIG. 1, a substrate processing apparatus includes an index module 10, a treating module 20, and a controller 30. According to the exemplary embodiment, the index module 10 and the treating module 20 are disposed along one direction. Hereinafter, a direction in which the index module 10 and the treating module 20 are disposed is referred to as a first direction 91, and when viewed from above, a direction vertical to the first direction 91 is referred to as a second direction 92, and a direction perpendicular to both the first direction 91 and the second direction 92 is referred to as a third direction 93.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 92. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 92.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal is the second direction 92 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 93, and movable along the third direction 93. A plurality of hands 122 are provided to be spaced apart in the vertical direction, and the hands 122 may move forwardly and backwardly independently of each other.

The treating module 20 includes a buffer unit 200, a transfer chamber 300, and a treating chamber 400. The buffer unit 200 provides a space in which the substrate W loaded into the treating module 20 and the substrate W unloaded from the treating module 20 stay temporarily. The treating chamber 400 performs a treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction 91. The buffer unit 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 92. The buffer unit 200 may be located at one end of the transfer chamber 300.

According to the example, the liquid treating chambers 400 are respectively disposed on both sides of the transfer chamber 300. At each of both sides of the transfer chamber 300, the liquid treating chambers 400 may be provided in an array of A×B (each of A and B is 1 or a natural number larger than 1) in the first direction 91 and the third direction 93.

The transfer chamber 300 includes a transfer robot 320. A guide rail 340 having a longitudinal direction in the first direction 91 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 93, and movable along the third direction 93. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction 93. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

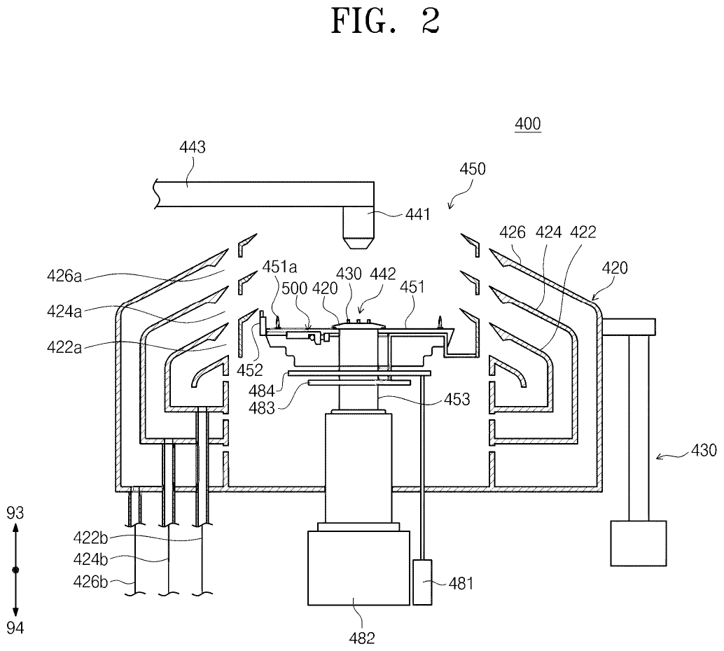

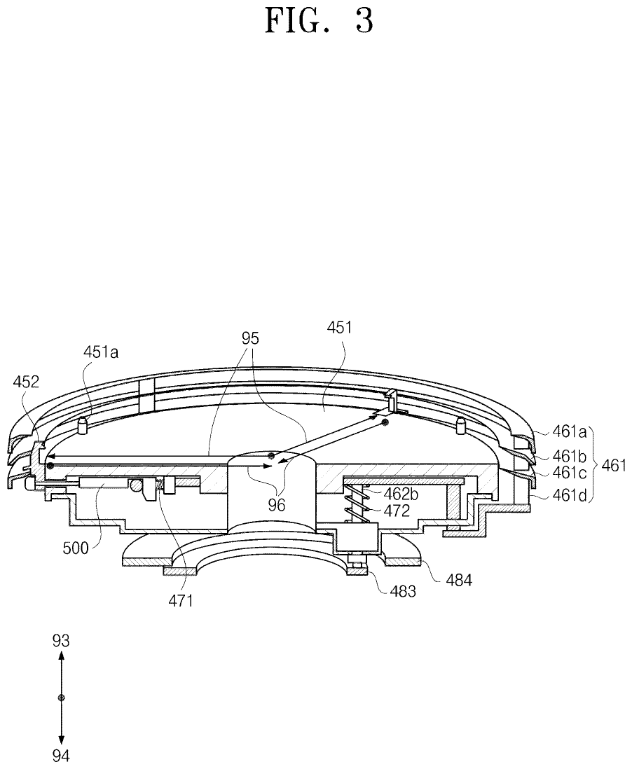

FIG. 2 is a diagram schematically illustrating an exemplary embodiment of the liquid treating chamber of FIG. 1, and FIG. 3 is a diagram illustrating the support unit and the guide ring unit in the liquid treating chamber of FIG. 2 in more detail. Referring to FIGS. 2 and 3, the liquid treating chamber 400 includes a housing 410, a cup body 420, a lifting unit 430, a liquid supply unit 440, a support unit 450, a guide ring unit 460, a driving unit 480, and a controller.

The housing 410 is provided in a generally rectangular parallelepiped shape. The housing provides an inner space. The configurations to be described below may be disposed in the housing 410. An opening (not illustrated) provided as a passage for the substrate W may be formed at a side portion of the housing 410.

The cup body 420 has a treatment space with an open top, and the substrate W is liquid-treated in the treatment space. The relative height between the cup body 420 and the support units 450 is adjusted by the lifting unit 430. The cup body 420 includes a plurality of cups. A plurality of cups is provided to surround different cups. A plurality of cups may recover different treatment liquids for each cup. According to the example, the cup body 420 includes a plurality of cups 422, 424, and 426. Each of the cups 422, 424, and 426 has a recovery space for recovering a liquid used to process the substrate. Each of the recovery containers 422, 424, and 426 is provided in a ring shape surrounding the support unit 450. When the liquid treatment process is in progress, the treatment liquid scattered by the rotation of the substrate W is introduced into the recovery space through inlets 422a, 424a, and 426a of the respective recovery containers 422, 424, and 426. According to the example, the cup body 420 includes an inner cup 422, an intermediate cup 424, and an outer cup 426. The inner cup 422 is disposed to surround the support unit 430, the intermediate cup 424 is disposed to surround the inner cup 422, and the outer cup 426 is disposed to surround the intermediate cup 424. A second inlet 424a through which the liquid flows into the intermediate cup 424 may be located above a first inlet 422a through which the liquid flows into the inner cup 422, and a third inlet 426a through which the liquid flows into the outer cup 426 may be located above the second inlet 424a. A first discharge pipe 422b through which the treatment liquid recovered through the first inlet 422a is discharged may be connected to the bottom of the inner cup 422. A second discharge pipe 424b through which the treatment liquid recovered through the second inlet 424a is discharged may be connected to the bottom of the intermediate cup 424. A third discharge pipe 426b through which the treatment liquid recovered through the third inlet 426a is discharged may be connected to the bottom of the outer cup 426.

The lifting unit 430 moves the cup body 420 in the vertical direction. By the up and down movement of the cup body 420, a relative height between the cup body 420 and the substrate W is changed. Accordingly, since the cups 422, 424, and 426 for recovering the treatment liquid are changed according to the type of liquid supplied to the substrate W, the liquids may be separated and recovered.

The liquid supply unit 440 supplies the treatment liquid to the substrate supported by the support unit 450. The liquid supply unit 440 includes a first nozzle 441 and a second nozzle 442. The first nozzle 441 supplies a first treatment liquid to the upper surface of the substrate W supported by the chuck pin 432. The first nozzle 441 is supported by a nozzle support 443. The nozzle support 443 moves the first nozzle 441 between a process position and a waiting position. The first nozzle 441 supplies the first treatment liquid to the substrate W placed on the support plate 451 at the process position, and the nozzle 441 which completes the supply of the first treatment liquid waits at the waiting position. According to the example, the first treatment liquid may be chemical or ultrapure water. The second nozzle 442 may be provided as a back nozzle. When the second nozzle is provided as a back nozzle, the second nozzle 442 is installed on the upper surface of the support plate 451 to be described later. Also, a through-hole for installing a bag nozzle may be formed in the center of the support plate 451. The second nozzle 442 supplies a second treatment liquid to the lower surface of the substrate W supported by the chuck pin 432. According to the example, the second treatment liquid may be ultrapure water.

The support unit 450 supports the substrate W in the treatment space. The support unit 450 includes a support plate 451, a chuck pin 452, a rotating shaft 453, and a chuck pin support 500.

The support plate 451 supports the substrate W. The upper surface of the support plate 451 is generally provided in a circular shape, and may have a larger diameter than the substrate W. A support pin 451a for supporting a rear surface of the substrate W is provided in the central portion of the support plate 451. A plurality of support pins 451a is provided. The support pins 451a are arranged to have an annular ring shape as a whole by combination thereof. The support pin 451a is provided with a top end protruding from the support plate 451 such that the substrate W is spaced a certain distance from the support plate 451. A space is formed inside the support plate 451. The chuck pin support 500, the first elastic member 471, and the second elastic member 472 to be described later may be installed inside the support plate 451. Hereinafter, a radial direction away from a center of the support plate 451 is referred to as a fifth direction 95, and a direction opposite to the fifth direction 95 is referred to as a sixth direction 96.

The rotating shaft 453 is provided to be rotatable by a second driver 452. The rotating shaft 453 is fixedly coupled to the center of the lower surface of the support plate 451. Accordingly, the second driver 456 to be described later may rotate the support plate 451.

The chuck pin 452 supports a side portion of the substrate W so that the substrate W is not separated from the support unit 450 when the substrate W is rotated. According to the example, a groove 452a is formed in the chuck pin 452, and the substrate W is supported by the groove 452a. The chuck pin 452 is provided at an edge portion of the support plate 451. The chuck pin 452 is disposed to be farther from the center of the support plate 451 than the support pin 451a. The chuck pin 452 is provided to protrude upwardly from the support plate 451. A plurality of chuck pins 452 is provided. The chuck pin 452 is provided to be movable in a radial direction of the support plate 451. The chuck pin 452 is provided to be movable between a support position C1 and a spaced position C2. The support position C1 is a position at which the chuck pin 452 supports the side portion of the substrate W placed on the support plate 452. The chuck pin 452 is located at the support position C2 during the treatment of the substrate W. The spaced position C1 is a position where the chuck pin 452 is spaced apart from the substrate W. When the substrate W is loaded into or unloaded from the support unit 450, the chuck pin 452 is positioned at the spaced position C1. According to the example, the chuck pin 452 may be provided to linearly move between the supporting position C1 and the spaced position C2.

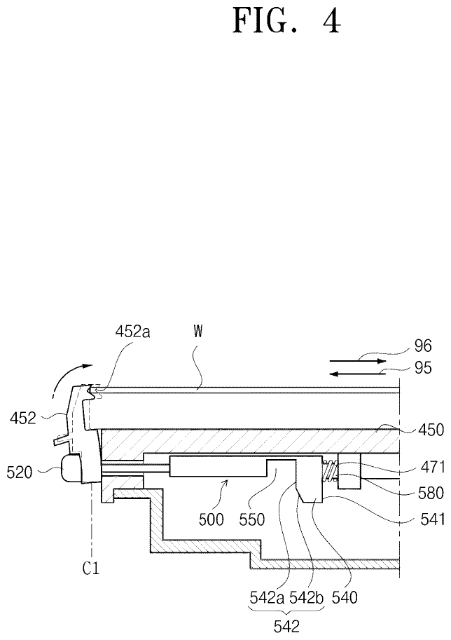

FIG. 4 is a diagram illustrating the chuck pin and the chuck pin support when the chuck pin supports a substrate in the liquid treating chamber of FIG. 2. Referring to FIG. 4, when the substrate W is not present, the groove 452a of the chuck pin at the support position C1 is provided to be closer to the center of the substrate W than to the end of the substrate W. Accordingly, when the chuck pin 452 supports the substrate W, the chuck pin 452 is provided in a curved state, and restoring force of the chuck pin 452 allows the chuck pin 452 to support the substrate W.

The chuck pin support 500 is provided by the number corresponding to the number of chuck pins 452. One chuck pin 452 is coupled to each chuck pin support 500. The chuck pin support 500 is provided inside the support plate 451. The chuck pin support 500 is provided to be moved in the fifth direction 95 or the sixth direction 96. According to the example, a guide part 454 for inducing movement in the fifth direction 95 or the sixth direction 96 is provided inside the support plate 451, and the chuck pin support 500 may be installed in the guide part 454. The chuck pin support 500 extends outside the support plate 451 along the fifth direction 95. The chuck pin support 500 penetrates a sidewall of the support plate 451. The chuck pin 452 is coupled to an outer end 510 of the chuck pin support 500. According to the example, the outer end 510 of the chuck pin support is inserted into a lower portion of the chuck pin 452, and the chuck pin 452 is fixed by a fixing member 520.

The chuck pin support 500 has an extension part 540 extending in the fourth direction 94 from an inner end 530 of the chuck pin support. The extension part 540 has a first sidewall 541 facing the rotating shaft 453 and a second sidewall 542 at an opposite side. The second sidewall 542 includes a vertical surface 542a and an inclined surface 542b. The vertical surface 542a is located above the inclined surface 542b. The inclined surface 542b has a shape extending from the vertical surface 542a. The inclined surface 542b is formed to be inclined downward in a direction toward the rotating shaft 453. The inclined surface 542b may be provided as a flat surface or a curved surface. A groove 550 may be formed in an area adjacent to the second sidewall 542. The groove 550 may be provided in a shape in which a lower portion is open. The groove 550 may be provided in a shape in which a contact part 462a, which will be described later, is inserted. When the groove 550 is formed, the vertical surface 542a may be a part of a sidewall of the groove.

A first elastic member 471 is installed at the inner end 530 of the chuck pin support 500. The first elastic member 471 is installed along the fifth direction 95 of the chuck pin support 500. The first elastic member 471 may be installed on the support 451b extending from the upper surface of the support plate 450 to the inside of the support plate 450. The first elastic member 471 is compressed when the chuck pin 452 is at the support position C1. The chuck pin 452 may move to the spaced position C2 by the first elastic member 471. According to the example, the first elastic member 471 may be provided as a spring.

The guide ring unit 460 guides the treatment liquid scattered from the substrate W to the cup body 420. The guide ring unit 460 may include a guide ring 461 and a guide ring support 462. The guide ring 461 may be provided adjacent to the support plate 451. The guide ring 461 may be provided to surround the support plate 451. The guide ring 461 may be provided to be inclined downwardly in a direction away from the support plate 451. The guide ring 461 may be provided to be inclined in a direction between the fourth direction 94 and the fifth direction 95. Also, the guide ring 461 may have a shape formed to be inclined further downwardly than the guide ring 461 from an end of the guide ring 461. Accordingly, the guide ring may be provided to be inclined in two stages.

The guide ring 461 includes an upper ring 461a, an intermediate ring 461b, a lower ring 461c, and a fixing rod 461d. The upper ring 461a, the intermediate ring 461b, and the lower ring 461c are provided to overlap when viewed from above. The upper ring 461a is located above the intermediate ring 461b. The intermediate ring 461b is located between the upper ring 461a and the lower ring 461c. The lower ring 461c is located at a position facing the upper ring in the up and down direction. The lower ring 461c, the intermediate ring 461b, and the upper ring 461a are located in the third direction 96 in the order of the lower ring 461c, the intermediate ring 461b, and the upper ring 461a. The upper ring 461a, the intermediate ring 461b, and the lower ring 461c are coupled to the fixing rod 461d. The fixing rod 461d may be provided to penetrate the edge regions of the upper ring 461a, the intermediate ring 461b, and the lower ring 461c in the third direction 93. Also, the guide ring support 462 may be connected to the fixing rod 461d.

The guide ring support 462 is located below the guide ring 461. The guide ring 461 is installed on the guide ring support 462 by the fixing rod 461d. The guide ring support 462 is inserted into the support plate 451 by penetrating the lower end of the support plate 451. The contact part 462a is formed on the guide ring support 462. The contact part 462a is provided by the number corresponding to the number of chuck pin supports 500. The contact part 462a may include a curved surface on its surface. According to the example, a vertical cross section of the contact part 462a may be circular, and a horizontal cross section thereof may be rectangular. The contact part 462a is formed to be in contact with the extension part while the guide ring unit 460 moves to the process position P2. When the guide ring unit 460 is in the waiting position P1 and the chuck pin 452 is in the spaced position C2, the contact part 462a is formed to overlap the inclined surface 542b when viewed from above. The contact part 462a is formed at a position where the guide ring unit 460 is in contact with the inclined surface 542b of the extension part when the guide ring unit 460 ascends to the process position P2. The contact part 462a may be formed to be inserted into the groove 550 when the guide ring support is in the process position P2.

The contact part 462a is formed to be closer to the rotating shaft 453 than the extension part 540. According to the example, when the guide ring unit 460 moves from the waiting position P1 to the process position P2, the contact part 462a is in contact with the inclined surface 542b and moves while pushing the inclined surface 542b.

A connection part 462b is formed on the guide ring support 462. The connection part 462b has a shape extending in the fourth direction 94 from a portion of the guide ring support 462 inserted into the support plate 451. The connection part 462b is coupled to the first driver 481. The guide ring support 462 may include a plurality of connection parts 462b. When a plurality of connection parts 462b are provided, the connection part 462b and the chuck pin support 500 may cross each other in the support plate 451. According to the example, three chuck pin supports 500 and three connection parts 462b are provided, respectively, and when viewed from above, the connection parts 462b-1 are disposed to form 120 degrees with respect to each other, and the connection part 462b-1 is disposed between the pin support 500-1 and the chuck pin support 500-2, and the chuck pin support 500-2 may be disposed between the connection part 462b-1 and the connection part 462b-2. The connection part 462b may be separably provided. Accordingly, the guide ring unit 460 and the first driver 481 are separated from each other, and the guide ring unit 460 may rotate together with the support unit 450.

A second elastic member 472 is installed inside the support plate 451. The second elastic member 470 may be provided in a compressed state in the fourth direction 94. One end of the second elastic member 472 may be provided to be in contact with a lower wall of the support plate 451. The other end of the second elastic member 472 may be provided to be in contact with the guide ring support 462. According to the example, the second elastic member 472 may be provided as a spring, and the connection part 462b may be inserted into the spring. Accordingly, the guide ring unit 460 may be lifted in the third direction 93 by an elastic force of the second elastic member 472.

The driving unit 480 may include a first driver 481 and a second driver 482. The first driver 481 is connected to the guide ring support 462. The guide ring support 462 may be moved in the third direction 93 or the fourth direction 94 by the first driver 481. According to the example, the first driver 481 may be provided as a cylinder. The first driver 481 moves the guide ring unit 460 between the waiting position P1 and the process position P2. The waiting position P1 may be a position where the guide ring unit 460 is lowered. The waiting position P1 may be a position where a relative height with respect to the support plate 451 is lower. The waiting position PI may be a position where interference does not occur with the transfer robot 320 that transfers the substrate W while the substrate W is loaded in or unloaded from the support plate 451. The process position P2 may be a position where the guide ring unit 460 is raised. The process position P2 may be a position where a relative height with respect to the support plate 451 is higher than that of the waiting position P1. The process position P2 is a position at which the treatment liquid scattered while the substrate W is being treated may be separated and guided. The second driver 482 provides rotational force to the rotating shaft 483. Accordingly, the substrate W supported on the support plate 481 may be liquid-treated while rotating.

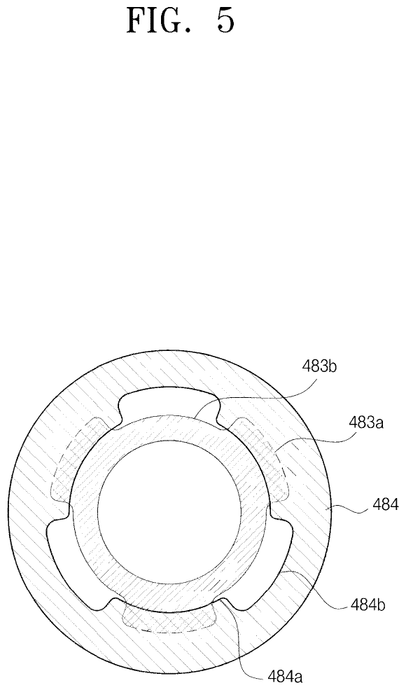

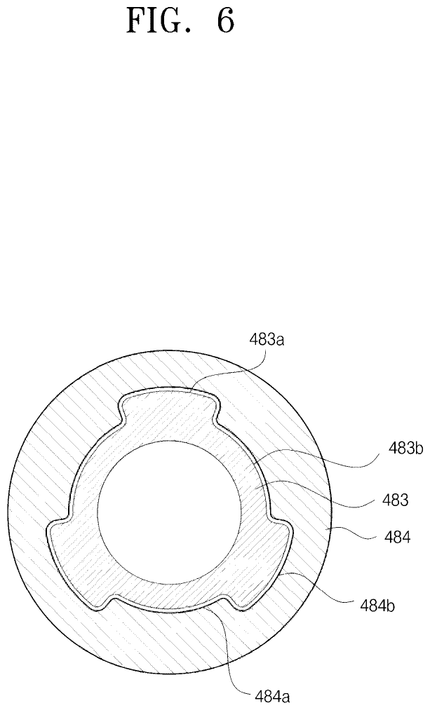

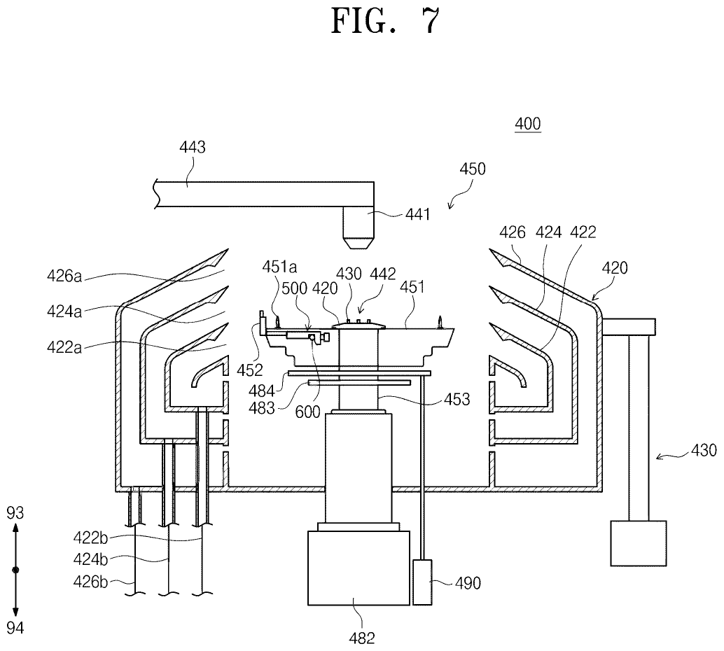

According to the example, the driving unit 480 may further include a first plate 483 and a second plate 484. In this case, the first plate 483 may be connected to the guide ring support 462, and the second plate 484 may be connected to the first driver 482. The first plate 483 may have a shape surrounding the rotating shaft 453. The first plate 483 may be provided as a ring-shaped plate. A first protrusion 483a and a first groove 483a may be formed at an outer side of the first plate 483. A plurality of first protrusions 483a and a plurality of first grooves 483a may be provided. The second plate 484 may be provided as a ring-shaped plate. The second plate 484 may have a shape surrounding the first plate. The second plate 484 may be located above the first plate 483. The second plate 484 may be provided to be spaced apart from the first plate 483 in the third direction 96. A second groove 484a may be formed at the inner side of the second plate 484 in the position and shape corresponding to the first protrusion. Also, a second protrusion 484a may be formed in the position and shape corresponding to the first groove 483a. Accordingly, the first plate 483 and the second plate 484 may form a key groove structure. The first plate 483 may rotate together with the spin chuck 451 by the second driver 482. FIG. 5 is a diagram illustrating a state viewed from above when the first plate and the second plate are at the first position, and FIG. 6 is a diagram illustrating a state viewed from above when the first plate and the second plate are at the second position. Referring to FIGS. 5 and 7, as the first plate 483 rotates, the first protrusion 483a and the second protrusion 484a may partially or entirely overlap each other, when viewed from above. This position is defined as a first position R1. Also, a position where the first protrusion 483a and the second protrusion 484a do not overlap is defined as a second position R2. According to the exemplary embodiment, the first plate 483 and the second plate 484 may always be located at the first position R1 except when the spin chuck 451 is managed or replaced.

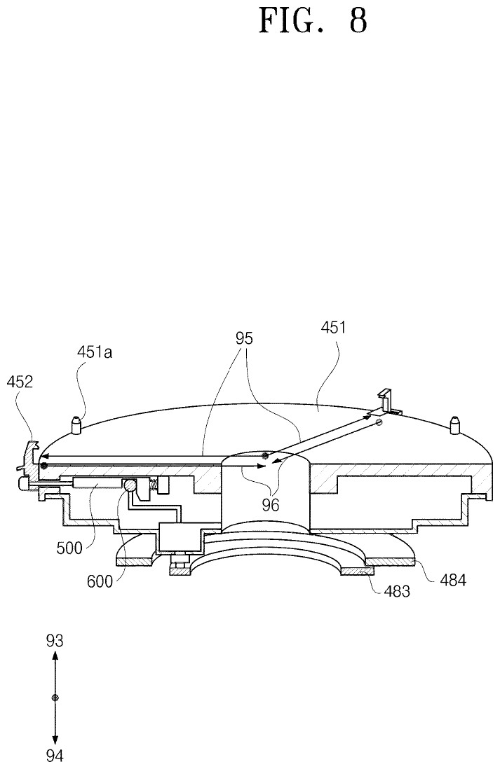

FIG. 7 is a diagram schematically illustrating another exemplary embodiment of the liquid treating chamber of FIG. 1, and FIG. 8 is a diagram illustrating the support unit of FIG. 7 in more detail. Hereinafter, a configuration overlapping the above-described example is equally applied to the present exemplary embodiment, and a description thereof will be omitted, and a configuration added or changed will be described. Referring to FIGS. 7 and 8, the liquid treating chamber 400 may include a housing 410, a cup body 420, an elevation unit 430, a liquid supply unit 440, a support unit 450, a contact part 600, and a driver 490. Unlike the above-described example, the present exemplary embodiment does not include the guide ring unit 460.

The contact part 600 may be one in which the contact part 462a formed on the above-described guide ring support 462 is separately provided. The contact part 600 is provided by the number corresponding to the number of chuck pin supports 500. The contact part 600 may include a curved surface on a surface contacting the inclined surface. According to the example, a vertical cross section of the contact part 600 may be a circle, and a horizontal cross section thereof may be a quadrangle. When the chuck pin 452 is at the spaced position C2, the contact part 600 is provided so that the contact part is provided to partially overlap the inclined surface 542b when viewed from above. The contact part is in contact with the vertical surface 542a when the chuck pin 452 is at the support position C2. Also, when viewed from above, the extension part 540, the contact part 600, and the chuck pin 452 are provided to be sequentially aligned along a direction away from a center of the support plate 451.

The driver 490 may be the first driver 481 described above. The driver 490 is connected to the contact part 600. The driver 490 moves the contact part 600 in the up and down direction. The contact part 600 is raised by the driver 490 to be in contact with the inclined surface 542b and to push the inclined surface 542, and the chuck pin 452 is moved from the spaced position C2 to the support position C1.

Hereinafter, a process of loading the substrate W, treating the substrate W, and unloading the substrate W by using the substrate processing apparatus according to the exemplary embodiment of the present invention will be described.

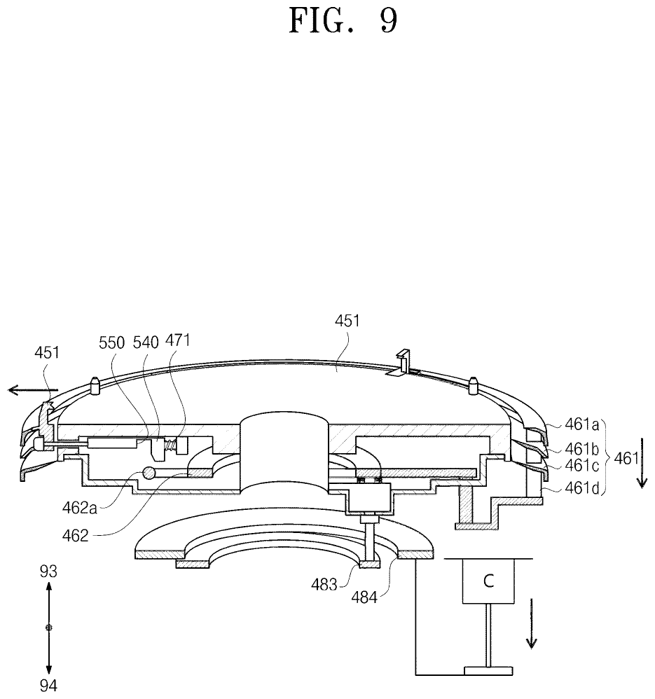

FIG. 9 is a cross-sectional view illustrating a cross-section of the liquid treating chamber according to the exemplary embodiment of the present invention before a substrate is loaded onto the support unit. Referring to FIG. 9, the guide ring unit 460 is located at the waiting position P1. The first driver 481 drives the guide ring unit 460 in the fourth direction 94. The second elastic member 472 is compressed in the fourth direction 94. The chuck pin 452 is located at the spaced position C2. The first elastic member 471 pushes the chuck pin support 500 in the radial direction. Then, the transfer robot 320 loads the substrate W into the support plate 451.

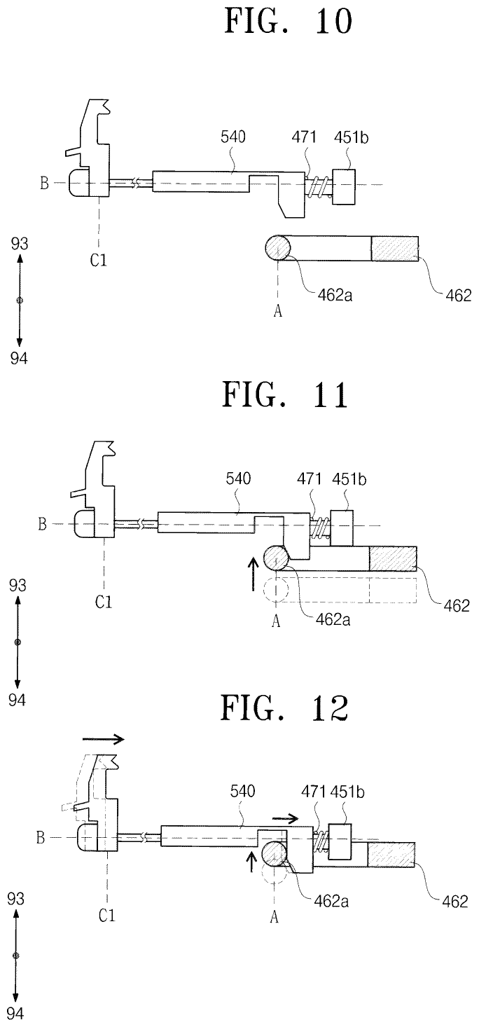

FIG. 10 to FIG. 13 are diagrams illustrating the appearance of the extension part and the contact part while the guide ring unit moves to the process position and the chuck pin moves to the support position. Referring to FIGS. 10 to 13, the first driver 471 is driven to move the guide ring unit 460 in the third direction 93. The second elastic member 472 applies elastic force to the guide ring unit 460 in the third direction 93. The guide ring unit 460 is moved to the process position P2. While the guide ring unit 460 is moved to the process position P2, the contact part 462a is also moved in the third direction. The contact part 462a is in contact with the extension part 540. The contact part 462a is moved along the A axis. The A axis is an axis parallel to the third direction 93. The extension part 540 is moved along the B axis. The B axis is an axis parallel to the fifth direction 95. The contact part 462a is in contact with the inclined surface 542b of the extension part. The contact part 462a applies force in a direction perpendicular to the surface of the extension part 540. The force is divided into a component in a direction toward the center of the upper surface of the support plate 451 and a component in the third direction 93. The vertical component is offset by installation of the chuck pin support 500 in the guide part 454. Accordingly, the extension part 540 is moved in a direction toward the center of the upper surface of the support plate 451 by the force of the horizontal component. Accordingly, the chuck pin 452 may be moved from the spaced position C2 to the support position C1. The contact part 462a is continuously moved in the third direction 93 while pushing the inclined surface 542b of the extension part 540. Thereafter, when the chuck pin 452 is positioned at the support position C1, the contact part 462a is in contact with the vertical surface 542a of the extension part.

During the above process, the first elastic member 471 is compressed in a direction toward the center of the support plate 451.

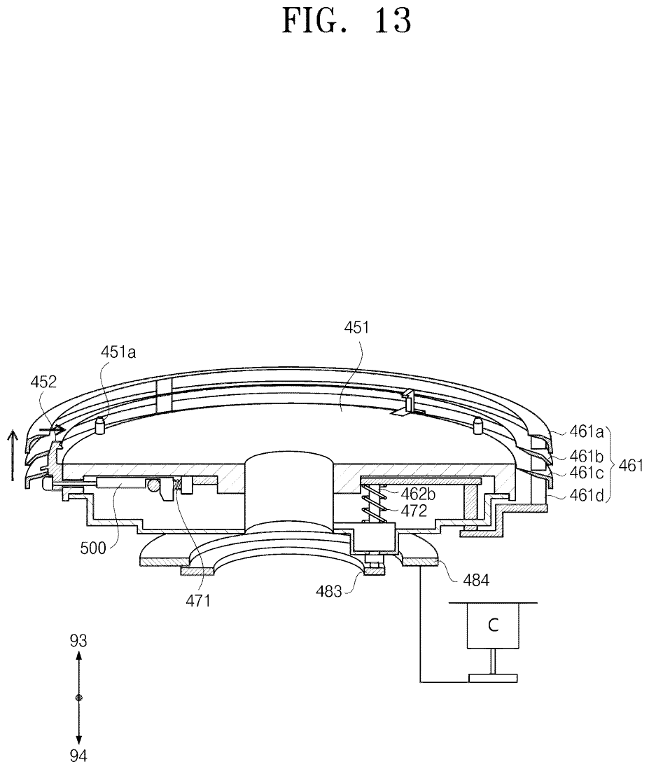

FIG. 14 is a diagram illustrating a state of treating a substrate in the liquid treating chamber according to the exemplary embodiment of the present invention. Referring to FIG. 14, the chuck pin 452 rotates together with the support plate 451 by the second driver 482. Centrifugal force is generated between the chuck pin 452 and the chuck pin support 500. Due to the centrifugal force, the chuck pin 452 moves in a radial direction of the upper surface of the support plate 451, such that support force of the chuck pin 452 supporting the substrate W may be weakened. However, even if the chuck pin 452 tries to move away from the substrate W, the extension part 540 of the chuck pin support is blocked from moving in a radial direction of the upper surface of the support plate 451 by the contact part 462a.

When the treatment of the substrate is terminated, the separated connection part 462b is coupled again. The first driver 481 moves the guide ring unit 460 in the fourth direction. The guide ring unit 460 moves to the waiting position P1. The second elastic member 472 is compressed in the fourth direction 94. The contact part 462a moves in the fourth direction 94. The contact part 462a sequentially passes through the vertical surface 542a and the inclined surface 542b of the extension part. While the contact part 462a passes through the inclined surface 542b, the first elastic member 471 moves the chuck pin support 500 in the fifth direction 95. Accordingly, the chuck pin 452 moves to the spaced position C2. The substrate W is supported again by the support pin 451a. Thereafter, the transfer robot 320 unloads the substrate W from the support plate 451.

According to the exemplary embodiment of the present invention, even if the rotational speed of the support unit 450 increases and the centrifugal force applied to the chuck pin 452 becomes strong, since the contact part 462a is disposed on the movement path of the extension part 540, the extension force 540 may offset the force to advance in the fifth direction 95 by the centrifugal force. Accordingly, even if the rotational speed of the support unit 450 increases, the chuck pin 452 may be prevented from moving in the fifth direction, thereby preventing the support force from being reduced by the centrifugal force. Further, by removing the configuration for compensating the centrifugal force, deformation or damage may be prevented by preventing excessive stress from being applied to the chuck pin 452 and the substrate W.

Furthermore, the separation and recovery rate of the treatment liquid may be improved by installing the guide ring unit 460 between the support plate 451 and the cup body 420. In addition, even if the guide ring unit 460 is provided, when the substrate W is loaded into the support unit 450 or unloaded from the support unit 450, the chuck pin 452 is moved to the spaced position C2 at the same time, so the interference between the guide ring unit 450 and the transfer robot 320 may be removed.

Furthermore, since the chuck pin 452 and the guide ring unit 460 are simultaneously driven by one first driver 481 without the installation of a separate driver, the complexity of the structure may be avoided.

Furthermore, since the first elastic member 470 applies elastic force to the guide ring unit 460 in the third direction 93, it is possible to prevent the guide ring unit 460 from descending or the chuck pin 452 from being away from the support position C1 when the support plate 451 rotates.

In addition, a back nozzle may be provided to the support unit 450 because the support unit 450 is fixed during the transfer process of the substrate W.

In the above-described example, the present invention has been described based on the case where only the first nozzle is provided as the nozzle for supplying the treatment liquid to the upper surface of the substrate W as an example. However, the present invention is not limited thereto, and a plurality of nozzles may be provided to supply a treatment liquid to the upper surface of the substrate W. In this case, the added nozzle may supply another type of treatment liquid to the substrate. In addition, the added nozzles are supported by different arms, and may be moved independently. Optionally, the first nozzle 452 and the added nozzle may be mounted on the same arm and moved simultaneously.

In addition, in the above-described example, the present invention has been described based on the case where the substrate W is treated with the treatment liquid as an example. However, the present invention is not limited thereto, and a configuration of injecting dry gas onto the substrate W may be added to dry the treatment liquid.

Also, in the above example, the present invention has been described based on the case where the extension part 462b is provided integrally with the guide ring support 462 as an example. However, the present invention is not limited thereto, and the extension part 462b may be provided as a separate configuration and coupled to the guide ring support 462.

What is claimed is:

1. An apparatus of treating a substrate, the apparatus comprising:
a cup body having a treatment space therein and an open top;
a support unit for supporting a substrate within the treatment space;
a liquid supply unit for supplying a treatment liquid to a substrate supported by the support unit; and
a contact part provided to be movable in an up and down direction,
wherein the support unit includes:
a support plate on which the substrate is placed and which is provided to be rotatable;
a chuck pin provided on the support plate and supporting the substrate on a side portion of the substrate; and
a chuck pin support that is coupled to the chuck pin and supports the chuck pin, and
the contact part is in contact with an inclined surface formed on the chuck pin support when the contact part rises,
the chuck pin is provided to move between a spaced position and a support position by an up and down movement of the contact part,
the spaced position is a position spaced apart from the substrate supported by the support unit, and
the support position is a position that supports the side portion of the substrate supported by the support unit.

2. The apparatus of claim 1, wherein when the chuck pin is located at the support position, the chuck pin support is blocked from moving in a direction away from a enter of the support plate by the contact part disposed on a movement path of the chuck pin support.

3. The apparatus of claim 1, wherein the chuck pin is moved to the spaced position by a first elastic member installed on the chuck pin support.

4. The apparatus of claim 2, wherein the inclined surface is formed at a lower end of an extension part formed by extending in a vertical direction from an inner end of the chuck pin support, and
the extension part includes a vertical surface that is in contact with the contact part when the chuck pin is positioned at the support position.

5. The apparatus of claim 1, wherein when the chuck pin is in the spaced position, the inclined surface and the contact part are provided to partially overlap when viewed from above, and
the contact part has a surface contacting the inclined surface in a form of a curved surface.

6. The apparatus of claim 1, wherein the inclined surface is provided to be inclined downwardly toward the support plate.

7. The apparatus of claim 1, further comprising:
a guide ring unit for guiding the treatment liquid scattered from the substrate to the cup body; and
a driver for adjusting a height of the guide ring unit,
wherein the guide ring unit further includes:
a guide ring for guiding a treatment liquid scattered from the substrate to the cup body; and
a guide ring support in which the guide ring is installed, and
the contact part is formed on the guide ring support.

8. The apparatus of claim 7, wherein the driver adjusts a height of the guide ring unit so that the guide ring unit is located at a process position and a waiting position,
the process position is a position higher than the support plate,
the waiting position is a position lower than the support plate, and
the chuck pin is moved to the support position when the guide ring unit is moved to the process position, and is moved to the spaced position when the guide ring unit is moved to the waiting position.

9. An apparatus of treating a substrate, the apparatus comprising:
a cup body having a treatment space therein and an open top;
a support unit for supporting a substrate within the treatment space;
a liquid supply unit for supplying a treatment liquid to an upper surface of the substrate supported by the support unit;
a guide ring unit for guiding the treatment liquid scattered from the substrate to the cup body; and
a driver for adjusting a height of the guide ring unit,
wherein the support unit includes:
a support plate on which the substrate is placed and which is provided to be rotatable;
a chuck pin provided on the support plate and supporting the substrate on a side portion of the substrate; and
a chuck pin support coupled to the chuck pin and supporting the chuck pin, and
wherein the guide ring unit further includes:
a guide ring for guiding a treatment liquid scattered from the substrate to the cup body; and
a guide ring support in which the guide ring is installed, and
the guide ring unit is moved by the driver between a process position, which is a position higher than the support plate, and a waiting position, which is a position lower than the support plate, and
the guide ring support is in contact with the chuck pin support to move the chuck pin while the guide ring unit is being moved.

10. The apparatus of claim 9, wherein the chuck pin is provided to be movable between a support position and a spaced position by the chuck pin support,
the support position is a position where the chuck pin supports the substrate on a side portion of the substrate, and
the spaced position is a position where the chuck pin is spaced apart from the substrate.

11. The apparatus of claim 10, wherein the chuck pin support is formed with an extension part extending in a vertical direction from an inner end of the chuck pin support,
the guide ring support is formed with a contact part that is in contact with the extension part when the guide ring unit is moved to the process position, and
when viewed from above, the extension part and the contact part partially overlap each other while the guide ring unit has moved to the waiting position, and the extension part is located to be closer to the rotating shaft than the contact part.

12. The apparatus of claim 11, wherein a sidewall of the extension part includes an inclined surface,
the inclined surface is provided to be inclined downwardly toward the rotating shaft, and
a surface of the contact part is formed with a curved surface.

13. The apparatus of claim 12, wherein as the guide ring unit moves to the process position, the contact part contacts a vertical wall of the sidewalls of the extension part, and
the chuck pin moves from the spaced position to the support position.

14. The apparatus of claim 13, wherein a second elastic member is provided at an inner end of the chuck pin support, and
the second elastic member is provided to be compressed when the chuck pin is moved to the support position.

15. The apparatus of claim 9, wherein the treatment liquid is provided as a first treatment liquid or a second treatment liquid different from the first liquid,
the guide ring includes:
an upper ring;
a lower ring facing the upper ring in an up and down direction; and
an intermediate ring disposed between the upper ring and the lower ring, and
the upper ring, the intermediate ring, and the lower ring are fixed to each other by a fixing rod, and
the fixing rod is coupled to the guide ring support, and
when the guide ring unit is located in the process position, a height of the intermediate ring corresponds to a height of the substrate supported by the support unit.

16. The apparatus of claim 15, wherein the liquid supply unit includes:
a first nozzle for discharging the first treatment liquid to an upper surface of the substrate; and
a second nozzle for discharging the second treatment liquid to a lower surface of the substrate.

17. The apparatus of claim 16, wherein the cup body includes a plurality of cups,
the plurality of cups is provided to surround different cups, and
the first treatment liquid and the second treatment liquid are recovered into different cups.

18. An apparatus of treating a substrate, the apparatus comprising:
a cup body having a treatment space therein and an open top;
a support unit for supporting a substrate within the treatment space;
a guide ring unit for guiding the treatment liquid scattered from the substrate to the cup body; and
the liquid supply unit including a first nozzle for supplying a first treatment liquid to an upper surface of the substrate supported by the support unit and a second nozzle for supplying a second treatment liquid to a lower surface of the substrate, and
a driving unit for driving the guide ring unit and the support unit,
the cup body includes a plurality of cups,
the plurality of cups is provided to surround different cups, and
the first treatment liquid and the second treatment liquid are recovered into different cups,
the support unit includes:
a support plate on which the substrate is placed;
a chuck pin provided on the support plate and supporting the substrate on a side portion of the substrate;
a rotating shaft supporting the support plate at a center of a lower surface of the support plate; and
a chuck pin support for supporting the chuck pin by being coupled with the chuck pin,
the guide ring unit includes:
a guide ring for guiding the first treatment liquid and the second treatment liquid scattered from the substrate to the cup body; and
a guide ring support in which the guide ring is installed, and which is installed inside the support plate by penetrating from a lower portion of the support plate to an inside of the support plate, and
the guide ring unit is moved between a process position that is a position higher than the support plate and a waiting position that is a position lower than the support plate by the driving unit,
the driving unit includes:
a first driver for adjusting a relative height between the guide ring unit and the support plate; and
a second driver for rotating the rotating shaft,
a connection part connecting the guide ring unit and the first driver is detachably provided during treatment of the substrate,
the chuck pin is provided to be movable between a support position and a spaced position by the chuck pin support, and the support position is a position where the chuck pin supports the substrate on a side portion of the substrate, and the spaced position is a position where the chuck pin is spaced from the substrate,
the chuck pin support is formed with an extension part extending in a vertical direction from an inner end of the chuck pin support,
a sidewall of the extension part has a vertical surface, and an inclined surface which extends while being inclined downwardly from the vertical surface toward the rotating shaft,
the guide ring support is formed with a contact part that is in contact with the extension part when the guide ring unit is moved to the process position, and
a curved surface is formed on a surface of the contact part,
when the guide ring unit has moved to the waiting position, the extension part and the contact part partially overlap each other when viewed from above, and the extension part is located to be closer to the rotating shaft than the contact part,
when the guide ring unit moves to the process position, the contact part sequentially contacts the inclined surface and the vertical surface of the extension part to move the chuck pin from the spaced position to the support position, and
a second elastic member is provided at an inner end of the chuck pin support, and
the second elastic member is provided to be compressed when the chuck pin is moved to the support position.

19. The apparatus of claim 18, wherein the guide ring includes:
an upper ring;
a lower ring facing the upper ring in an up and down direction; and
an intermediate ring disposed between the upper ring and the lower ring, and
the upper ring, the intermediate ring, and the lower ring are fixed to each other by a fixing rod, and
the fixing rod is coupled to the guide ring support, and
when the guide ring unit is located in the process position, a height of the intermediate ring corresponds to a height of the substrate supported by the support unit.

20. The apparatus of claim 19, wherein a first elastic member is installed under the guide ring support, and
the first elastic member applies elastic force to the guide ring support so as to make the guide ring support face upwardly.
